(19) United States
(12) Patent Application Publication
(10) Pub. No.: US 2003/0222801 A1
(43) Pub. Date: Dec. 4, 2003

(54) Switching device for common keyboard, screen, and mouse

(75) Inventors: Cherng-Ying Ying, Taipei (TW); Ta-Lung Yu, Taipei (TW)

Correspondence Address: BRUCE H. TROXELL, SUITE 1404, 5205 LEESBURG PIKE, FALLS CHURCH, VA, 22041, US

(73) Assignee: ACTION STAR ENTERPRISE CO., LTD.

(21) Appl. No.: 10/180,034

(22) Filed: Jun. 27, 2002

(30) Foreign Application Priority Data
Jun. 3, 2002 (TW) 91208100

(51) Int. Cl. H03M 11/00; H03K 17/94

(52) U.S. Cl. 341/26; 345/168

(57) ABSTRACT

The invention that discloses a switching device for common keyboard, screen, and mouse can make several sets of computer hosts (CPUs) alternatively use a keyboard, a screen, and a mouse, etc., and through the invention, any set of computer may be chosen to be connected to those keyboard, screen, and mouse. The invention includes a human interface device processing unit, a compiler, a multiplexer, and a hub. The human interface device processing unit may process the signal of a human interface device (HID). The compiler has a firmware to receive the signal output from the human interface device processing unit. The multiplexer is controlled by the signal output from the compiler to decide in choosing which computer host to be connected. The hub is controlled by the human interface device processing unit to be acted as a signal assembly-and-transmission.

### FIELD OF THE INVENTION:

The invention relates to a switching device for common keyboard, screen, and mouse to make several sets of computer hosts alternatively share a screen, a keyboard, and a mouse and, through the invention, a specific set of computer may be chosen to connect to those screen, keyboard, and mouse; particularly, a switching device possessing both hotkey function and switching control is applied to choose a specific set of computer.

### BACKGROUND OF THE INVENTION:

Accordingly, the computer has already penetrated into each family and enterprise to become a dispensable electronic product in modern living. Following the prevalence of computer multi-media, more accessory products are needed as output-and-input devices. Since the popularity of computer and its price can be accepted by most ordinary user, so a user sometimes needs to simultaneously possess more than one set of computer (PC) under many conditions. As everybody knows, a set of personal computer is comprised of nothing but a computer host (CPU), a display screen, a keyboard, and a mouse, etc. and, of course, it may also include a printer or other accessory devices such as multi-media devices. It is no doubt that the computer host, the display screen, the keyboard, and the mouse, etc. are almost the most basic equipment. When a user needs to use more than two sets of personal computer simultaneously and, if all these equipment are placed together, there will be lots of space in occupation, particularly, for those display screens. Ordinary, only one method can be applied; that is, plural sets of computer systems share a screen, a keyboard, and a mouse; in other words, multiple sets of computer host (CPU) alternatively use a screen, a keyboard, and a mouse.

Besides, in an ordinary computer industry and many testing circumstances, it sometimes needs to put a developing product into different computer systems for tests. At this time, it is unnecessary to distribute a screen to each individual computer host, because only one set of screen is just needed for the tester to monitor the testing result in each computer.

Please refer to FIG. 1, which is an illustration for plural sets of computer host alternatively using a common screen according to the prior arts. As shown in FIG. 1, for plural sets of computer host 10, 11, 12, a set of common screen 2 is used through a switching operation of the so-called KVM switch 5 (K: keyboard, V: screen, and M: mouse), which can be switched simultaneously among plural sets of computer host 10, 11, 12, such that only one set of screen 2 is needed for displaying both the working situation and executing result for each set of computer 10, 11, 12 alternatively, besides only one set of keyboard 3 and one piece of mouse 4 are needed for the user to input the data into or make a controlling operation into the plural sets of computer host 10, 11, 12 alternatively or simultaneously. In other words, both the keyboard 3 and the mouse 4 are the common input devices for the computer hosts 10, 11, 12, and the screen 2 is the common output device for the computer hosts 10, 11, 12, while the KVM switch 5 is provided for acting as a conversion interface among each computer host 10, 11, 12 and also for transmitting the data input from both the keyboard 3 and the mouse 4 into the switched computer host, from which the resulting information is displayed on the screen 2.

Please refer to FIG. 2, which is an internal block diagram for the electric KVM switch according to prior arts. As shown in FIG. 2, it is exemplified a device capable of switching two sets of computer host 10, 11. The KVM switch 5 is constructed as an electric switching structure, so it is arranged with key-pushing switch 52. Through the control of the key-pushing switch 52, a switching operation can be made between the two sets of computer host 10, 11 by the KVM switch, so a multiplexer is also provided for a switching function for two computer hosts 10, 12. However, the shortcoming of this kind of electric device is that it is impossible to be controlled through the keyboard to reach an effect of switch.

Please refer to FIG. 3, which is an internal block diagram for the key-controlling KVM switch according to prior arts. As shown in FIG. 3, the interior of the KVM switch is comprised of a primary-and-secondary control IC 62, a compiler 61, and a multiplexer 60. Through the hotkeys on the keyboard 3, this kind of prior art may make a switching control of electric type without applying a switch. The primary-and-secondary control IC 62 is mainly applied for intercepting and interpreting the information package transferred from the keyboard 3 in a USB configuration. Through both the instructional compilation of the firmware relative to the compiler 61 and the choosing switch of the multiplexer 60, the controlling order or information coming from the keyboard 3 and the mouse 4 is transferred to the switched computer host. The shortcomings of this kind of prior art are that the price of the primary-and-secondary control IC 62 is expensive, its design is also complicated, therefore, the purchasing cost is very high and, an outward driving program is needed to complete the functional operation accurately. So, an improvement toward the directions of low cost and simple design to further enhance a new effect is indeed an innovation and breakthrough in this technique range.

### SUMMARY OF THE INVENTION

In order to overcome the shortcomings of above prior arts, the main objective of the invention is to make several sets of computer host that can share a set of screen, a set of keyboard, and a piece of mouse. Through the switching device disclosed by the invention, it may decide which set of computer to be able to use the screen, the keyboard, and the mouse. The characteristic of the invention is to design an IC in the switching device to be able to process the signal of a human interface device (HID); that is, the signal line of a USB interface is connected with the mouse inserting troughs and the keyboard inserting troughs among each computer and the USB interface is also connected to a set of keyboard and mouse. By applying the coexistence of the keyboard controlling function of the hotkey switch on the keyboard and the mechanical switching function, there are two kinds of choice at the same time.

The invention includes a human interface device processing unit, a compiler, a multiplexer, and a hub, etc. The human interface device processing unit may process the signal of a human interface device (HID) and be corresponded with the application program of a chosen computer host to generate mutual communication, such that it may receive the corresponding signal output from the application program when the chosen computer receives the controlling signal transferred from the keyboard. There is a firmware in the compiler to receive the signal output from the human interface device processing unit to process the relative instruction. The multiplexer is controlled by the signal output from the compiler to decide which computer host to be able to receive the signals from the screen, keyboard, and mouse. The hub is controlled by the human interface device processing unit and is connected with the multiplexer, screen, keyboard, and mouse to be acted as an assembly-and-transmission for the signals from the screen, keyboard, and mouse.

For your esteemed members of reviewing committee to further understand and recognize the merits of the present invention, a detailed description matching with corresponding drawings are presented as follows.

### BRIEF DESCRIPTION OF THE DRAWINGS

FIG. 1 is an illustration for a common screen shared by plural sets of computer host according to the prior arts.

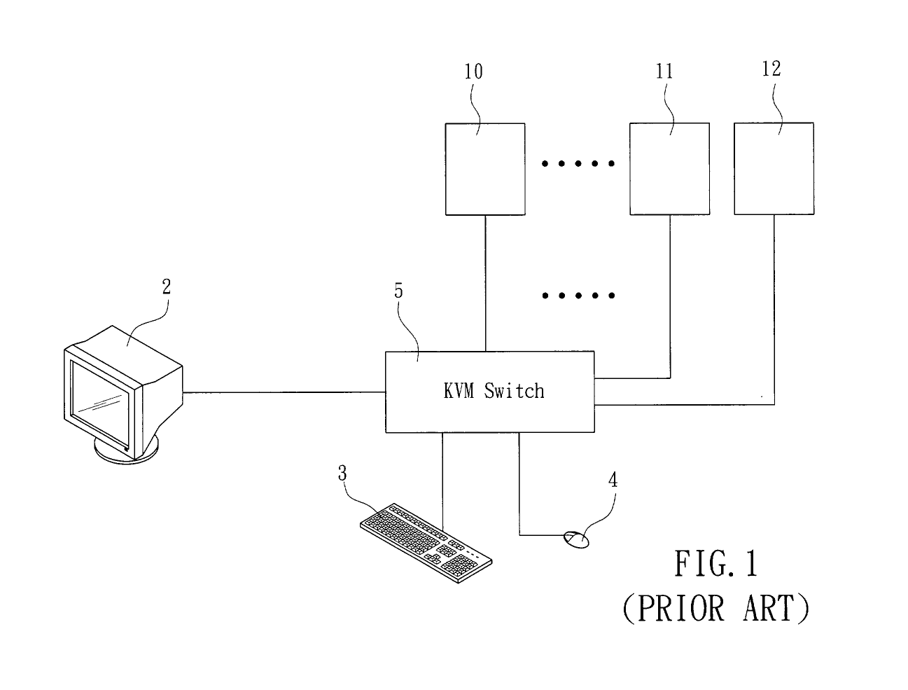

FIG. 2 is an internal block diagram of the key-pushing electric KVM switch according to the prior arts.

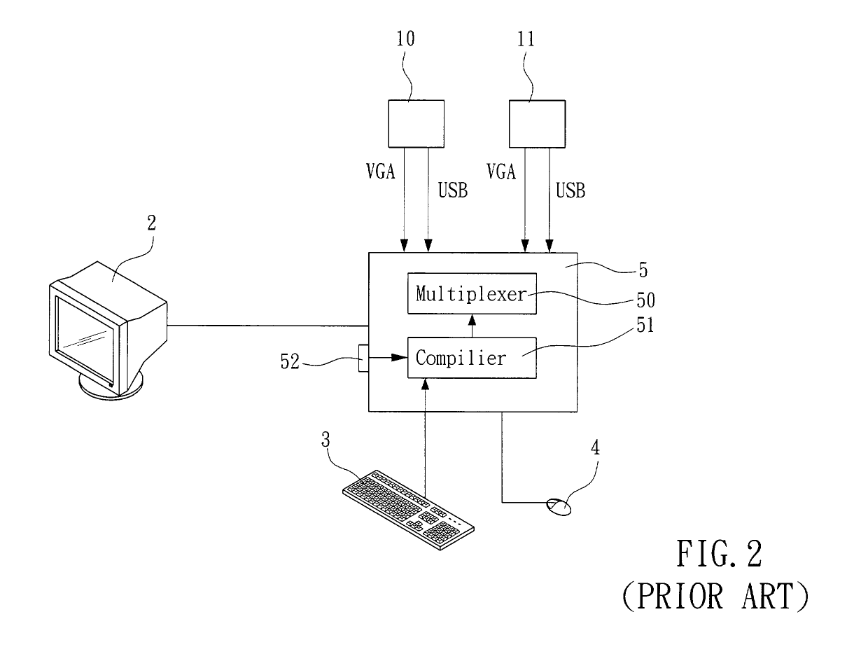

FIG. 3 is an internal block diagram of the key-controlling electric KVM switch according to the prior arts.

FIG. 4 is a preferable embodiment for the block diagram according to the invention.

### DETAILED DESCRIPTION OF THE INVENTION

The invention is a switching device (also called a KVM switch) for common keyboard, screen, and mouse, such that several sets of computer host may share a set of screen, a set of keyboard, and a piece of mouse; that is, through the function of the switching device disclosed by the invention, it may decide a specific set of computer host to use the screen, keyboard, and mouse. In other words, through the switching device, the signals input into the keyboard and mouse are connected to the chosen computer host and, through the switching device disclosed by the invention, the signal and the processed result of the chosen computer host are then connected to the screen and displayed.

The characteristic of the invention is to design an IC in the switching device to be able to process the signal of a human interface device. The interior of the switching device also applies this interface to process its signal. Since the signal line of the USB interface is connected to the inserting trough of the mouse and the inserting trough of the keyboard among each computer, so the keyboard and the mouse are also connected by the USB interface, and how many sets of USB interface ports to be designed in the switching device are depended on how many sets of computer host. Applying the keyboard control function of the hotkey switch on the keyboard, it may decided which computer host is the chosen object, and any set of computer host may be chosen as an object from the several connected sets of computer randomly through the hotkey switch. Only the chosen computer host then may receive the signal or the control sent out from the keyboard and mouse, and only the chosen computer may display its internal processing results on the screen.

In order to describe in more convenient way, the number of the connected computer host according to the invention is two. Actually, the invention may be applied on the computer host, of which number is more than two, such as: 4 sets, 8 sets, 16 sets, etc.

The detailed structure and its connection relationship according to the invention are described incorporating with the following drawings for facilitating your esteem member of reviewing committee to make a further understanding of the invention.

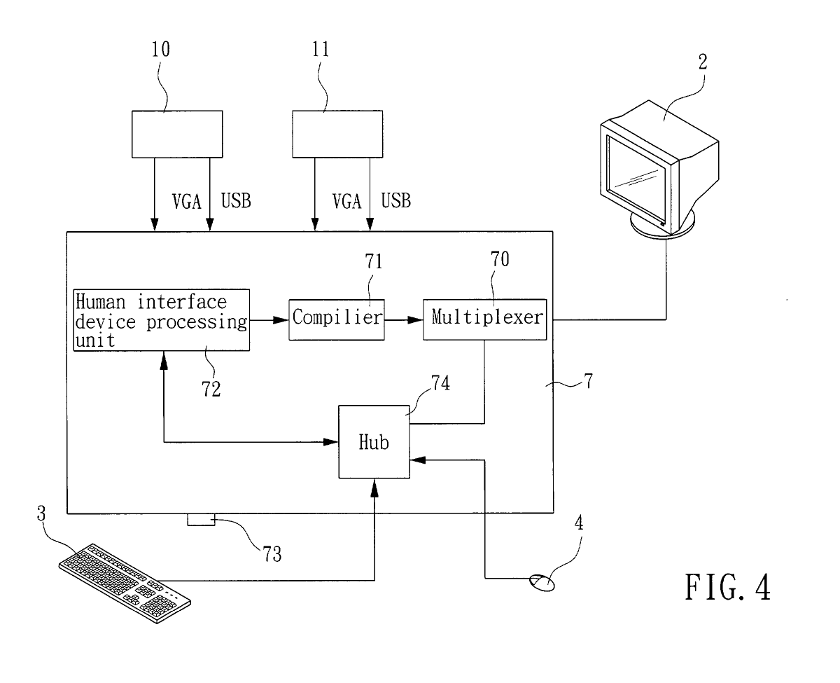

Please refer to FIG. 4, which is a preferable embodiment for the block diagram according to the invention. As shown in FIG. 4, the switching device 7 for the common keyboard, screen, and mouse according to the invention includes: a human interface device (HID) processing unit 72, a compiler 71, a multiplexer 70, and a hub 74, etc. The human interface device processing unit 72 may process the signal of a human interface device (HID) and be corresponded with the application program of the chosen computer host 10 or 11 to generate mutual communication, such that it may receive the corresponding signal output from the application program when the chosen computer 10 or 11 receives the controlling signal transferred from the keyboard 3 and, it is known at this time which computer host 10 or 11 has been chosen. The signal transferred from the keyboard 3 is a control signal that will decide which computer host will be chosen.

The compiler 71, which receives the signal output from the human interface device (HID) processing unit 72 for processing the relative instruction. Usually, there is a firmware in the compiler 71 for executing relative action. The multiplexer 70, which is controlled by the signal output from the compiler 71 to decide which computer host 10 or 11 can be connected to the screen 2 (the screen may be a CRT screen, a LCD, or other kinds of display screen, etc.), keyboard 3, and mouse 4; that is, it may decide which set of computer may receive the signals output from the keyboard 3 and the mouse 4 and display the processing results of the chosen computer host to the screen 2. The hub 74 is controlled by the human interface device processing unit 72 and is connected to screen 2, keyboard 3, and mouse. The hub 74 may be used as an assembly-and-transmission for the signal of the keyboard 3 and the mouse 4.

Therefore, when a user applies the hotkey control on the keyboard 3, the switching device 7 of the invention will process the signal and switch the operation to the chosen computer host, such that a connection state among the chosen computer host, keyboard 3, and mouse 4 is formed, so the user may randomly choose a connection to the computer host 10 or the computer host 11. If the former one is chosen (e.g., the computer host 10), then the computer host 10 receives the control signal or information input into the keyboard 3 and mouse 4 by the user. Through the process of the switching device 7, the computer host 10 and the screen 2 are formed as a connection state, so the state or the operation results of the computer host 10 may be displayed on the screen 2 instantly.

The human interface device processing unit 72 may be designed as an IC (or a chip pattern) with 16 or 18 pins, and both the human interface device processing unit 72 and the compiler 71 can be designed integrally in a same IC (or a chip pattern) depending upon the actual needs. Through the design of the human interface device processing unit 72, not only is the above function to choose specific set of computer host achieved, but also is the problem of the outward arrangement of a driving program according to the prior arts solved. Furthermore, the connection interface among the keyboard 3, the mouse 4, and the switching device 7 is a USB interface, while the connection interface among the keyboards and the mice of the computer host 10, 11 with the switching device 7 is also a USB interface, which may be matched with the operational process of the human interface device (HID) and make a transmission for the signals.

Furthermore, the invention may also be designed as key-pushing switch 73 to control the choice of computer hosts 10, 11 manually, so the invention is also has the manual function in additional to the hotkey controlling function in the keyboard and the both functions will not be interfered with each other, which is another characteristic of the invention as well.

Besides, the computer host may be the computer host of a personal computer (PC), an industrial computer, a sever host charging the serving function, or other kinds of computer host.

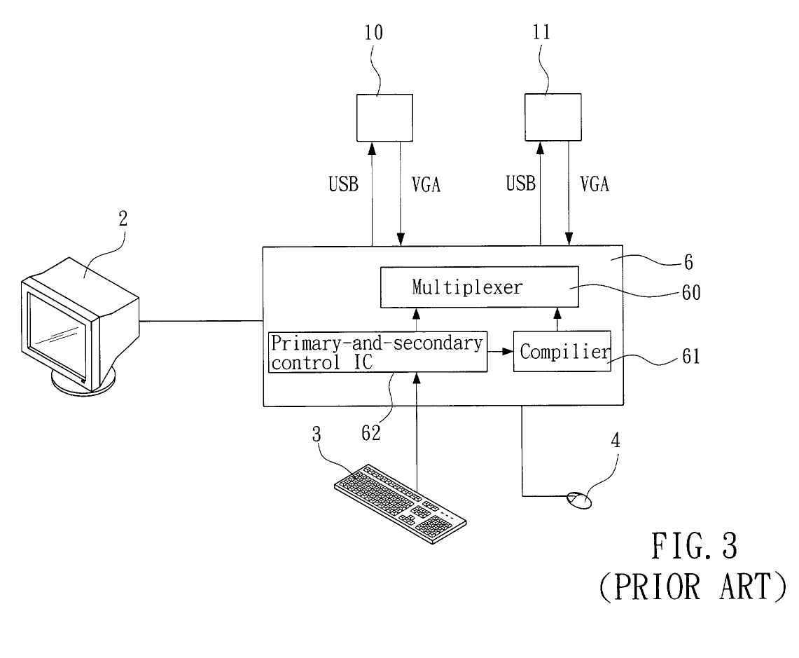

One thing is worthy of mentioning—the human interface device processing unit applied by the invention may be formed as an integrated circuit (IC), of which cost is far lower than that of the primary-and-secondary control IC 62 used in the prior arts as shown in FIG. 3. Usually, their cost difference is ten times, so the application of the invention can save the cost and enhance the competition ability. Additionally, the internal circuit structure of the invention further has an excellent improvement, which may get rid of the shortcoming according to the prior arts; namely, an outwardly driving program is needed to carry out the required function.

While the present invention has been shown and described with reference to preferred embodiments thereof, and in terms of the illustrative drawings, it should be not considered as limited thereby. Thus, the present invention is infinitely used. However, various possible modification, omission, and alterations could be conceived of by one skilled in the art to the form and the content of any particular embodiment, without departing from the scope and the sprit of the present invention.

The invention is disclosed and is intended to be limited only the scope of the appended claims and its equivalent area.

What is claimed is:

1. A switching device for common keyboard, screen, and mouse can make several sets of computer hosts share a screen, a keyboard, and a mouse, and it may decide which specific set of computer to be connected to the screen, keyboard, and mouse through the switching device, which includes:
a human interface device (HID) processing unit, which may process the signal of the human interface device and it is corresponded to the application program of the chosen computer host to receive the corresponding signal transferred from the application program when the chosen computer receives the control signal from the keyboard;
a compiler, which receives the signal output from the human interface device processing unit;
a multiplexer, which is controlled by the signal output from the compiler to decide which set of computer to be able to be connected to the screen, keyboard, and mouse; and
a hub, which is controlled by the human interface device processing unit and is also connected to the multiplexer, and which is connected to keyboard and the mouse as well.

2. The switching device for common keyboard, screen, and mouse according to claim 1, wherein the interface of the keyboard and the mouse between the computer and the switching device is a USB interface.

3. The switching device for common keyboard, screen, and mouse according to claim 1, wherein the interface between the keyboard, the mouse and switching device is a USB interface.

4. The switching device for common keyboard, screen, and mouse according to claim 3, wherein it further includes a switch, by which the switching device is controlled to decide which set of computer may be connected to the screen, the keyboard, and the mouse.

5. The switching device for common keyboard, screen, and mouse according to claim 1, wherein the said compiler has a firmware.

6. The switching device for common keyboard, screen, and mouse according to claim 1, wherein the said human interface device processing unit is an IC.

7. The switching device for common keyboard, screen, and mouse according to claim 1, wherein the said human interface device processing unit and the compiler are formed integrally as one IC.

8. The switching device for common keyboard, screen, and mouse according to claim 1, wherein the said human interface device processing unit is an IC of 18 pins.

9. The switching device for common keyboard, screen, and mouse according to claim 1, wherein the said human interface device processing unit is an IC of 16 pins.

10. The switching device for common keyboard, screen, and mouse according to claim 4, wherein the said human interface device processing unit is an IC.

11. The switching device for common keyboard, screen, and mouse according to claim 4, wherein the said human interface device processing unit and the compiler are formed integrally as one IC.

12. The switching device for common keyboard, screen, and mouse according to claim 4, wherein the said human interface device processing unit is an IC of 18 pins.

13. The switching device for common keyboard, screen, and mouse according to claim 4, wherein the said human interface device processing unit is an IC of 16 pins.

14. The switching device for common keyboard, screen, and mouse according to claim 1, wherein the said computer host is the computer host of a personal computer (PC).

15. The switching device for common keyboard, screen, and mouse according to claim 4, wherein the said computer host is the computer host of a personal computer (PC).

16. The switching device for common keyboard, screen, and mouse according to claim 1, wherein the said computer host is a computer host that may take charge as a server.

17. The switching device for common keyboard, screen, and mouse according to claim 4, wherein the said computer host is a computer host that may take charge as a server
